(19) United States
(12) Patent Application Publication
(10) Pub. No.: US 2008/0073030 A1
(43) Pub. Date: Mar. 27, 2008

(54) Apparatus for manufacturing semiconductor device

(75) Inventor: Kazumori Yoshino, Miyazaki (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/878,585

(22) Filed: Jul. 25, 2007

(30) Foreign Application Priority Data
Sep. 26, 2006 (JP) 2006-260042

(51) Int. Cl. H01L 21/306

(52) U.S. Cl. 156/345.11

(57) ABSTRACT

An apparatus according to the present invention, includes an etching solution tank which contains etching solution used for a wet etching process, a wet etching process to a semiconductor wafer being carried out in the etching solution tank; a nitrogen gas supply component which supplies a nitrogen gas (N2), which is used for a wet etching process in the etching solution tank; a flow regulating component which delivers the nitrogen gas (N2) supplied from said nitrogen gas supply component into said etching solution tank during a wet etching process, and which continues to deliver said nitrogen gas into said etching solution tank during a standby phase in which a wet etching process is not being performed; and a bubbling component which bubbles said nitrogen gas (N2), supplied from said nitrogen gas supply component, in said etching solution tank during a wet etching process.

### CROSS REFERENCE TO RELATED APPLICATION

This application claims the priority of Application No. 2006-260042, filed Sep. 26, 2006 in Japan, the subject matter of which is incorporated herein by reference.

### TECHNICAL FIELD OF THE INVENTION

The present invention relates to a method of manufacturing a semiconductor device which includes a wet etching process. In particular, the invention relates to an improved method of controlling nitrogen gas bubbling in the etching solution.

### BACKGROUND OF THE INVENTION

One of the steps involved in the manufacture of semiconductor devices is a wet etching step, used to form openings in an intermediate insulating film or PV film or the like. In such a wet etching step, ammonium fluoride, which is the main component of a chemical solution (etching solution), readily precipitates crystals which become suspended in the chemical solution and adhere to the film to be etched formed on the surface of the wafer dipped in the etching solution, thus impeding the etching process. FIG. 1 shows a case in which crystal precipitation 16 of ammonium fluoride has adhered to a film to be etched 12 on the surface of a wafer 10. In FIG. 1, reference numeral 14 indicates a resist layer.

In Japanese Unexamined Patent Publication No. Hei 7-58078, so-called “bubbling”, in which nitrogen gas is supplied into the chemical solution in the wet etching step, is performed in order to eliminate this problem. In the wet etching apparatus disclosed in Japanese Unexamined Patent Publication No. Hei 7-58078, as shown in FIG. 2, nitrogen gas is supplied into an etching solution 20 from a single nitrogen gas pipe 26. Furthermore, a nitrogen gas supply source 22 which supplies the nitrogen gas includes a timer, allowing nitrogen bubbling to be performed for a set period of time.

The wet etching apparatus shown in FIG. 2 includes an etching solution tank 18 which holds the etching solution 20, a filter 25 provided partway along the nitrogen gas pipe 26, a flow meter 24 which measures the flow rate of the nitrogen gas, and an electromagnetic valve 23. A plurality of semiconductor wafers 19 can be processed at one time in the etching solution tank 18. Furthermore, near the base of the etching solution tank 18, a bubbler 21, which bubbles the nitrogen gas flow, is provided.

Japanese Unexamined Patent Publication No. 2004-198243 discloses a manufacturing method for a three-axis acceleration sensor, which includes a wet etching process. The wet etching technique disclosed in Japanese Unexamined Patent Publication No. Hei 7-58078 can be applied to the manufacturing process for such a three-axis acceleration sensor.

However, according to the invention disclosed in Japanese Unexamined Patent Publication No. Hei 7-58078, because the supply of nitrogen is completely shut off by the electromagnetic valve (19) when nitrogen bubbling is not being performed (such as when the etching process itself is halted or the supply of nitrogen gas is stopped), etching fluid enters the end of the nitrogen supply pipe (16). This results in crystal precipitation inside the nitrogen supply pipe (16) which prevents the nitrogen bubbling from achieving its intended purpose (effect) to a sufficient extent.

On the other hand, if nitrogen gas bubbling is performed constantly (continually) throughout the wet etching process, the amount of side etching (undercutting) 38 increases as shown in FIG. 3, resulting in eave-like portions 40 of a resist 34 which tend to break easily. This can causes a problem in that broken-off portions of the resist 34 can become suspended in the etching solution and adhere to the film to be etched of the semiconductor wafer. Furthermore, an increase in the amount of undercutting decreases the dimensional accuracy of the product, which then may no longer meet the required specifications. In FIG. 3, reference numeral 30 indicates a silicon substrate, and reference numeral 32 indicates a layer to be etched.

When etching a MEMS product or the like in which the layer to be etched is thick, the product is dipped in the etching solution for a longer period of time, which presents an even greater risk of excessive undercutting.

### OBJECTS OF THE INVENTION

In accordance with the above circumstances, an object of the present invention is to provide a wet etching apparatus capable of effectively controlling crystal precipitation in the etching solution.

Another object of the present invention is to provide a semiconductor device manufacturing method capable of manufacturing high quality semiconductor devices by effectively controlling crystal precipitation in the etching solution.

Yet another object of the present invention is to provide a semiconductor device manufacturing method which can manufacture high quality semiconductor devices by suppressing undercutting of the resist while effectively controlling crystal precipitation in the etching solution.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

### (First Aspect of the Invention)

According to a first aspect of the present invention, an apparatus includes: an etching solution tank which contains etching solution used for a wet etching process, a wet etching process to a semiconductor wafer being carried out in the etching solution tank; a nitrogen gas supply component which supplies a nitrogen gas (N2), which is used for a wet etching process in the etching solution tank; a flow regulating component which delivers the nitrogen gas (N2) supplied from said nitrogen gas supply component into said etching solution tank during a wet etching process, and which continues to deliver said nitrogen gas into said etching solution tank during a standby phase in which a wet etching process is not being performed; and a bubbling component which bubbles said nitrogen gas (N2), supplied from said nitrogen gas supply component, in said etching solution tank during a wet etching process.

### (Second Aspect of the Invention)

According to a second aspect of the present invention, a method for manufacturing a semiconductor device includes the steps of: dipping a semiconductor wafer in an etching solution to perform a wet-etching process; supplying a nitrogen (N2) gas into the etching solution during the wet etching process; bubbling the nitrogen gas in the etching solution; and continuing to supply a nitrogen (N2) gas into the etching solution even during a standby phase in which a wet etching process is not being performed.

Preferably, a smaller amount of nitrogen gas is supplied into the etching solution during this standby phase than during an actual wet etching process. Here, the amount of nitrogen gas supplied during the standby phase is 10% or less of the amount of nitrogen gas supplied during an actual wet etching process.

Preferably, a nitrogen gas is supplied into the etching solution during a wet etching process on an intermittent basis at predetermined intervals. Here, a period of time in that the nitrogen gas is supplied into the etching solution during a wet etching process can be half of a period of time or less in that the semiconductor wafer is dipped in the etching solution. In addition, during a wet etching process, the nitrogen gas is preferably supplied into the etching solution for 1 to 3% of period of time in that the semiconductor wafer is dipped in the etching solution.

The etching solution preferably contains ammonium fluoride. The etching solution preferably also contains hydrofluoric acid and acetic acid.

The semiconductor device can be a three-dimension acceleration sensor with a MEMS structure.

### (Third Aspect of the Invention)

According to a third aspect of the present invention, a method for wet-etching a semiconductor wafer includes the steps of: dipping a semiconductor wafer in an etching solution; supplying a nitrogen (N2) gas into the etching solution during the wet etching process on an intermittent basis at predetermined intervals; and bubbling the nitrogen gas in the etching solution. A period of time in that the nitrogen gas is supplied into the etching solution during a wet etching process is half of a period of time or less in that the semiconductor wafer is dipped in the etching solution.

In the above described method according to the third aspect of the present invention, during a wet etching process, the nitrogen gas is preferably supplied into the etching solution for 1 to 3% of period of time in that the semiconductor wafer is dipped in the etching solution.

The etching solution preferably contains ammonium fluoride. The etching solution preferably also contains hydrofluoric acid and acetic acid.

The semiconductor device can be a three-dimension acceleration sensor with a MEMS structure.

### (Fourth Aspect of the Invention)

According to a fourth aspect of the present invention, a method for manufacturing a semiconductor device includes the steps of: dipping a semiconductor wafer in an etching solution; supplying a nitrogen (N2) gas into the etching solution during the wet etching process on an intermittent basis at predetermined intervals; and bubbling the nitrogen gas in the etching solution. A period of time in that the nitrogen gas is supplied into the etching solution during a wet etching process is half of a period of time or less in that the semiconductor wafer is dipped in the etching solution.

In the above described method according to the fourth aspect of the present invention, during a wet etching process, the nitrogen gas is preferably supplied into the etching solution for 1 to 3% of period of time in that the semiconductor wafer is dipped in the etching solution.

The etching solution preferably contains ammonium fluoride. The etching solution preferably also contains hydrofluoric acid and acetic acid.

The semiconductor device can be a three-dimension acceleration sensor with a MEMS structure.

In the present invention, by continuing to supply nitrogen gas into the etching solution tank even during the standby phase in which etching is not being performed, etching solution can be prevented from entering the end of the tube that supplies the nitrogen gas, which prevents crystals from forming inside the nitrogen gas supply tube.

Furthermore, in the present invention, by supplying (bubbling) nitrogen gas into the etching solution in a number of stages on an intermittent basis, undercutting of the etched layer can be reduced. As a result, a resist breakage can be minimized.

### BRIEF DESCRIPTION OF THE DRAWINGS

FIG. 1 is a cross-sectional view for describing problems inherent in conventional wet etching methods.

FIG. 2 is an explanatory diagram showing the basic structure of a conventional wet etching apparatus.

FIG. 3 is a cross-sectional view for describing problems inherent in conventional wet etching methods.

FIG. 4 is an explanatory diagram showing the basic structure of a wet etching apparatus according to an embodiment of the present invention.

FIG. 5A to FIG. 5F are cross-sectional views showing steps in the process of manufacturing a MEMS device (semiconductor device), including a wet etching step according to the embodiment of the present invention.

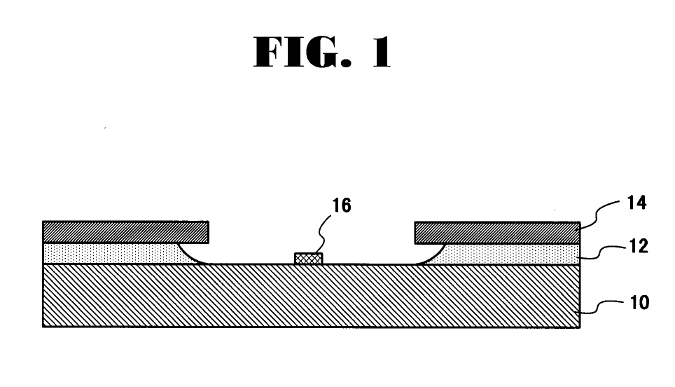

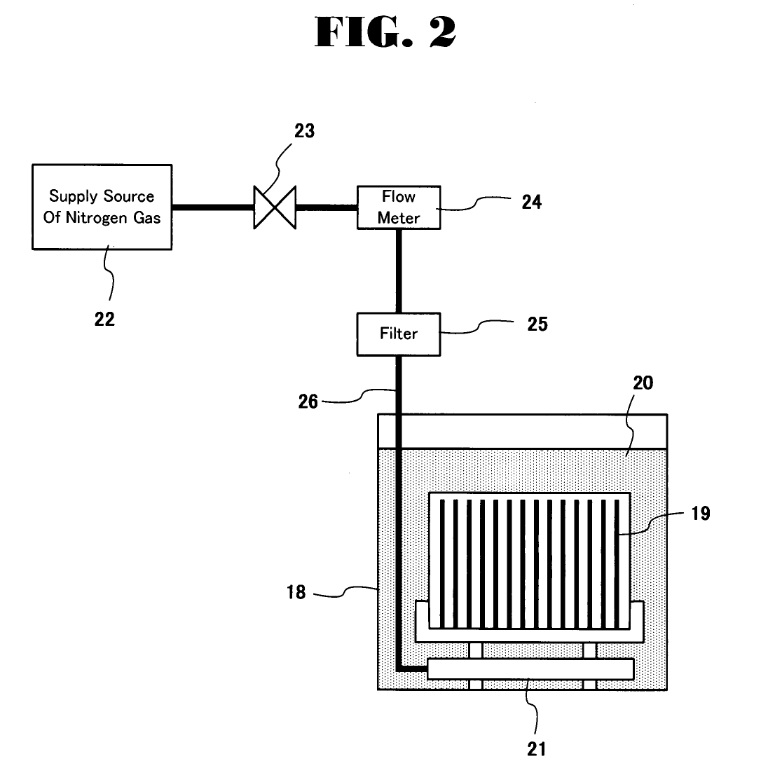

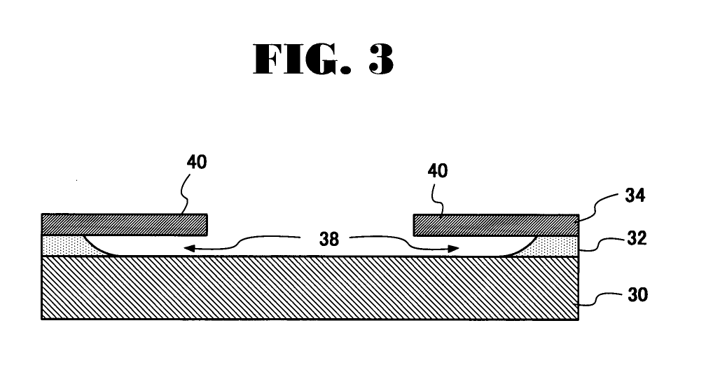

### BRIEF DESCRIPTION OF THE REFERENCE SYMBOLS

118 Etching solution tank
119 Semiconductor wafer
120 Etching solution
121 Bubbler
122 Nitrogen gas supply source
123 Electromagnetic valve
124a, 124b Flow meter
126a First pipe
126b Second pipe
129 Controller

### DETAILED DISCLOSURE OF THE INVENTION

In the following detailed description of the preferred embodiments, reference is made to the accompanying drawings which form a part hereof, and in which is shown by way of illustration specific preferred embodiments in which the invention may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present invention. The following detailed description is, therefore, not to be taken in a limiting sense, and scope of the present inventions is defined only by the appended claims.

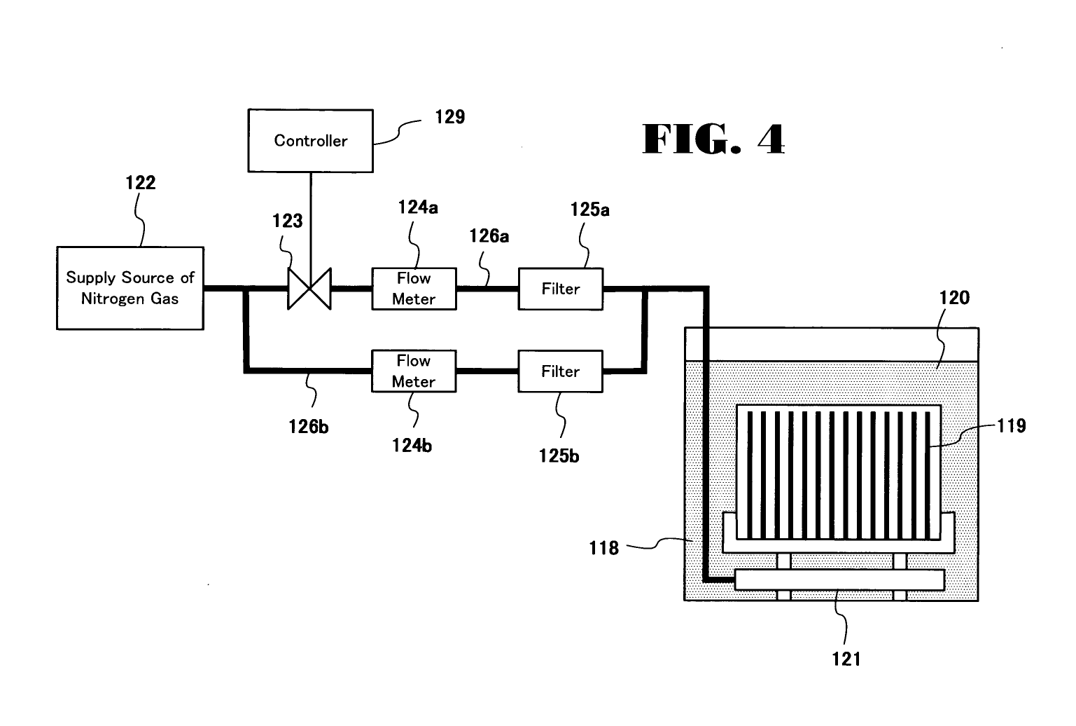

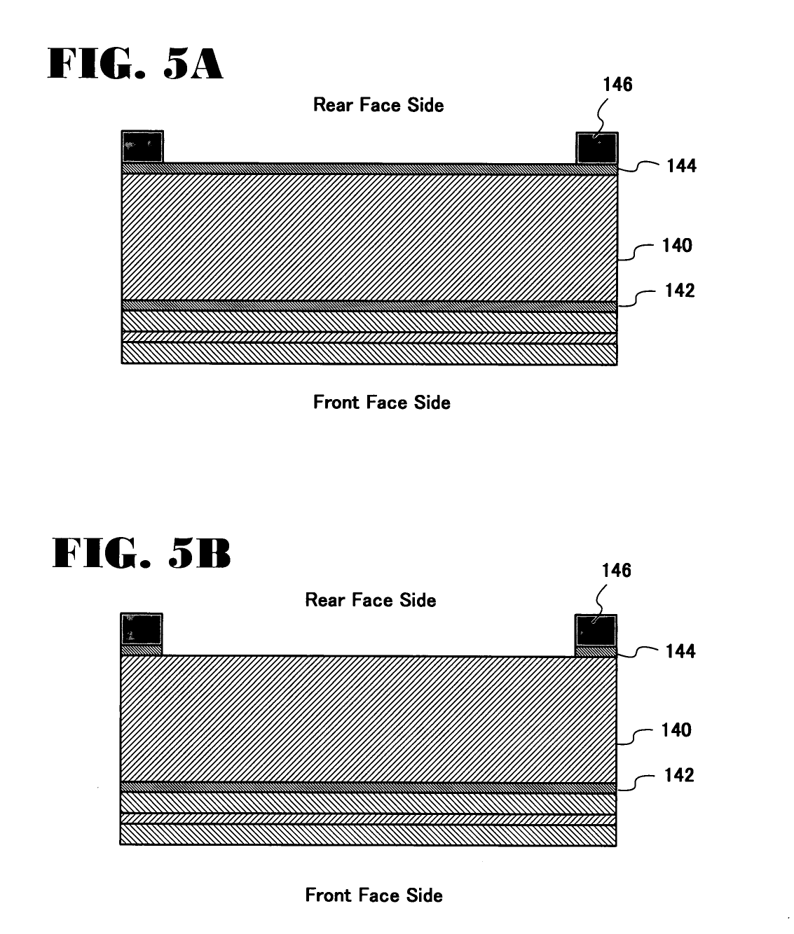

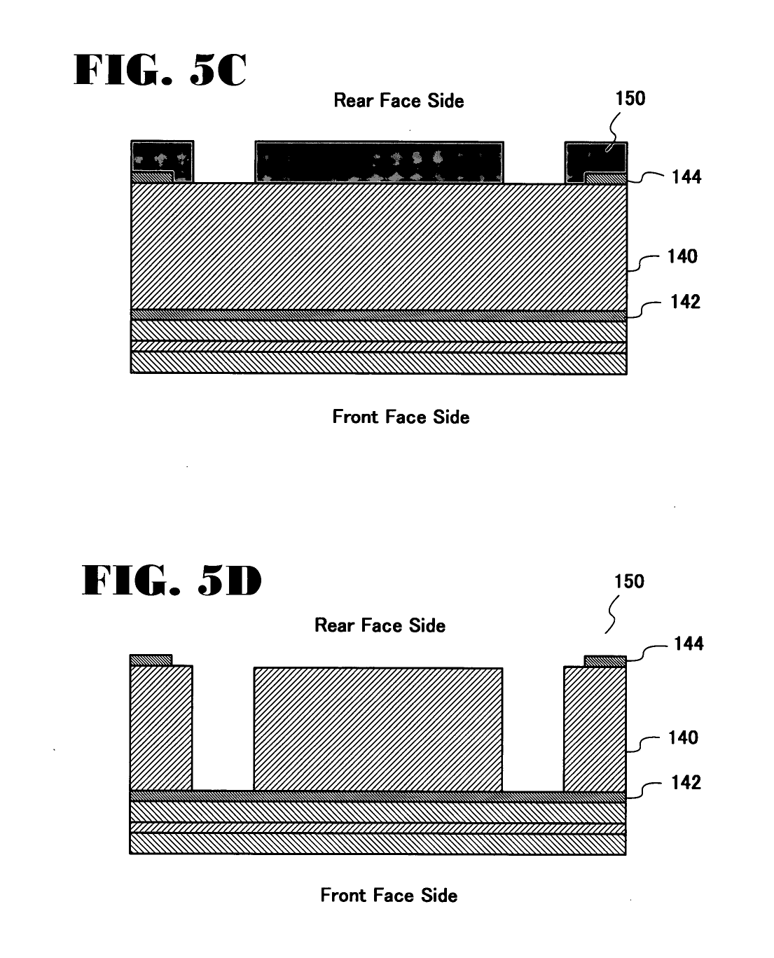

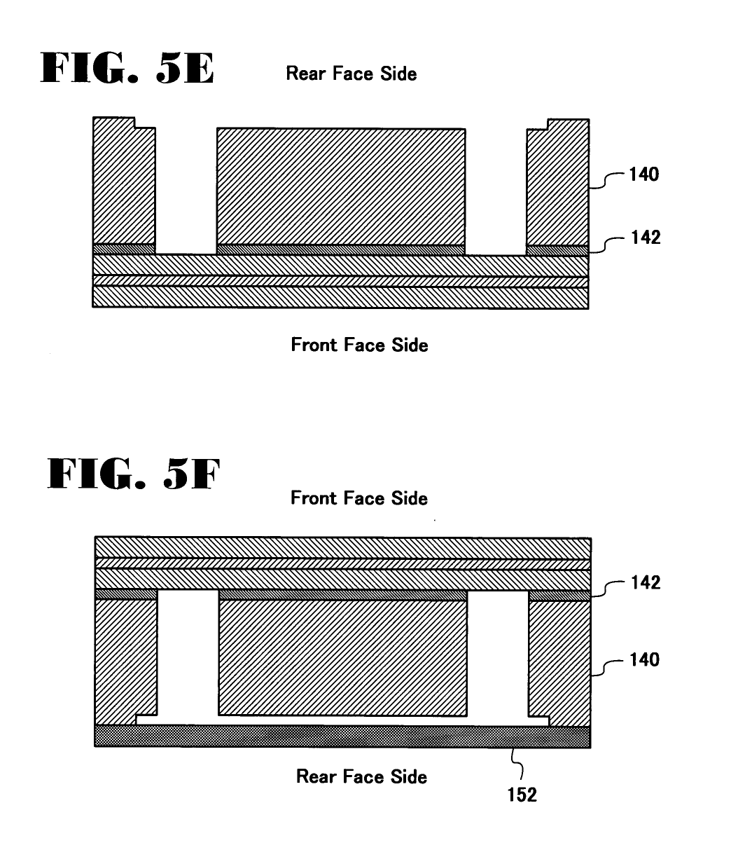

The best mode for carrying out the present invention is described in detail below with reference to FIG. 4, and FIG. 5A through FIG. 5F. FIG. 4 is an explanatory drawing showing the basic configuration of a wet etching apparatus according to an embodiment of the present invention. The wet etching apparatus according to an embodiment of the present invention includes an etching solution tank 118 which holds etching solution 118 used in the wet etching process, and inside of which a plurality of semiconductor wafers 119 which serve as the processing targets are subjected to a wet etching process. As the etching solution (etchant) 120, a mixed solution of hydrofluoric acid, ammonium fluoride, and acetic acid can be used. A wet etching process can be used to etch intermediate insulating films, nitride films, and oxide films subsequent to the metal wiring step.

Near the base of the etching solution tank 118, a bubbler 121, which bubbles the nitrogen gas flow, is provided below the semiconductor wafers 119.

The wet etching apparatus according to this embodiment also includes a nitrogen gas supply source 122 which supplies the nitrogen gas for the bubbling process, and a first pipe 126a which is connected to the nitrogen gas supply source 122 and delivers the nitrogen gas to the bubbler 121.

An electromagnetic valve 123, a flow meter 124a, and a filter 125a are provided along the first pipe 126a. The electromagnetic valve 123 controls the supply of nitrogen gas to the first pipe 126a by switching between open and closed (ON and OFF) under the control of a controller 129. By providing the measurement taken by the flow meter 124a to the controller 129, the flow rate of nitrogen gas into the first pipe 126a can be precisely controlled. The filter 125a removes foreign matter from the nitrogen gas flowing in the first pipe 126a, and is provided immediately upstream from the etching solution tank 118.

The wet etching apparatus according to this embodiment also includes a second pipe 126b, which is connected in parallel to the first pipe 126a via a bypass connection. The input end of the second pipe 126b is connected between the nitrogen gas supply source 122 and the electromagnetic valve 123. Furthermore, the output end of the second pipe 126b is connected between the filter 125a and the bubbler 121.

A flow meter 124b and a filter 125b are provided along the second pipe 126b. The flow meter 124b measures the flow rate of nitrogen gas along the second pipe 126b. By providing the measurement taken by the flow meter 124b to the controller 129, the flow rate of nitrogen gas into the second pipe 126b can be precisely controlled. The filter 125b removes foreign matter from the nitrogen gas flowing in the second pipe 126b, and is provided immediately upstream from the etching solution tank 118.

The flow rate of nitrogen gas in the first pipe 126a is greater than the flow rate of nitrogen gas in the second pipe 126b. For example, in the first pipe 126a which delivers the nitrogen gas used for bubbling, the nitrogen gas flows at a rate of 150 ml/min. On the other hand, in the second pipe 126b, the nitrogen gas flows at a rate of 10 ml/min. Preferably, the flow rate of nitrogen gas in the second pipe 126b is 10% or less of the flow rate of nitrogen gas in the first pipe 126a.

The second pipe 126 does not deliver gas for use in bubbling; it delivers only a small amount of gas so as to keep the interior of the pipe system at a positive pressure so that the etching solution does not enter the end of the pipe connected to the bubbler 121. The amount of nitrogen gas that needs to be delivered through the second pipe 126b to maintain the inside of the second pipe 126a at a positive pressure is determined based on such factors as the capacity of the etching solution tank 118.

In the present embodiment, during a wet etching process, the nitrogen gas (N2) supplied from the nitrogen gas supply source 122 is supplied into the etching solution tank 118 through the first pipe 126a. A small amount of gas is also supplied from the second pipe 126b.

The supply of nitrogen gas through the first pipe 126a takes place intermittently. Here, the period of time in that the nitrogen gas is supplied through the first pipe 126a is preferably half or less of the time in that the semiconductor wafers 119 are dipped in the etching solution 120 in the etching solution tank 118. More preferably, the period of time in that the nitrogen gas is supplied through the first pipe 126a is 1 to 3% of the time in that the semiconductor wafers 119 are dipped in the etching solution 120 in the etching solution tank 118.

For example, if a wet etching process is performed by dipping the semiconductor wafers 119 in the etching solution 120 in the etching solution tank 118 for 30 minutes, bubbling is performed at five minute intervals for 5 to 10 seconds each time.

During the standby phase in which a wet etching process is not being performed, the electromagnetic valve 123 is closed, and nitrogen gas is not supplied to the first pipe 126a. On the other hand, a small amount of nitrogen gas (10 ml/min) continues to be supplied to the second pipe 126b.

Next, a manufacturing process for a semiconductor device (a three-axis acceleration sensor with a MEMS structure) which applies the wet etching method of the present invention is described in basic terms with reference to FIG. 5 to FIG. 7. After subjecting the front face (active layer) side of an SOI wafer to predetermined processing, a resist protection coating is applied to this same front face. This is to prevent the front face side from being damaged by contact with conveyance systems or the like during processing of the rear face side.

Subsequently, the semiconductor wafer is flipped over, and using a balance oxide film (144) formed on the rear face of the SOI wafer, the Gap pattern to be used as a mask in a subsequent Gap-Si etching step is formed by a photolithographic technique. Next, the wafer surface is again subjected to resist coating, to repair the damage to the resist on the wafer surface. The resist is then dried by interbaking.

Next, as shown in FIG. 5(A), a resist 146 is patterned on the rear face of the wafer. Here, reference numeral 140 indicates a SOI support substrate, 142 indicates a BOX layer, and 144 indicates the balance oxide film.

Next, as shown in FIG. 5(B), the balance oxide film is selectively etched by a wet etching process according to the conditions of the present invention described above. After etching, the resist 146 is removed (peeled off). Here, the selectively etched oxide film 144 is used as a mask during subsequent Gap-Si etching of the rear face. The wet etching method according to the present invention is applied to the etching step shown in FIG. 5(B).

Next, another resist protection coating (not shown) is applied to the front face (active layer) side of the wafer, with an object of repairing damage to the surface of the active layer (front face side). In preparation of forming the weight of the semiconductor acceleration sensor on the rear face side of the wafer, as shown in FIG. (C), patterning of the resist 150 is performed.

Next, as shown in FIG. 5(D), using the resist 150 as a mask, etching of the silicon substrate (SOI support substrate) 140 is performed using a D-RIE apparatus. Subsequently, the resist 150 is removed (peeled off).

Next, using the selectively etched oxide film 144 as a mask, etching of the silicon substrate (SOI support substrate) 140 is performed using a D-RIE apparatus, thereby forming Gap regions except in areas corresponding to the oxide film 144, as shown in FIG. 5(E). The oxide film 144 is then removed by a wet etching process.

Next, Pyrex (registered trademark) glass 152 is affixed to the rear face of the wafer, to improve the rigidity of the sensor. Then, as shown in FIG. 5(F), the semiconductor wafer is flipped over again.

From this point onward, the three-axis acceleration sensor is brought to completion by using known methods to perform such steps as cleaning the wafer and then forming the beam structure.

The present invention can also be applied to the manufacture of semiconductor devices other than MEMS. Furthermore, the bubbling conditions (interval, bubbling time and the like) can be modified as appropriate according to such factors as the etching solution used, the capacity of the etching solution tank, and the number of wafers to be etched at one time.

What is claimed is:

1. An apparatus for manufacturing a semiconductor device, comprising:
an etching solution tank which contains etching solution used for a wet etching process, a wet etching process to a semiconductor wafer being carried out in the etching solution tank;
a nitrogen gas supply component which supplies a nitrogen gas (N2), which is used for a wet etching process in the etching solution tank;
a flow regulating component which delivers the nitrogen gas (N2) supplied from said nitrogen gas supply component into said etching solution tank during a wet etching process, and which continues to deliver said nitrogen gas into said etching solution tank during a standby phase in which a wet etching process is not being performed; and
a bubbling component which bubbles said nitrogen gas (N2), supplied from said nitrogen gas supply component, in said etching solution tank during a wet etching process.

2. An apparatus according to claim 1, wherein said flow regulating component comprises:
a first pipe which delivers said nitrogen gas into said etching solution tank during a wet etching process; and
a second pipe which delivers said nitrogen gas into said etching solution tank during a wet etching process and during said standby phase.

3. An apparatus according to claim 2, wherein
said first pipe is designed so as to deliver a greater amount of nitrogen gas into said etching solution tank than said second pipe.

4. An apparatus according to claim 3, wherein
said second pipe is designed so as to deliver 10% or less of the amount of nitrogen gas, delivered through said first pipe, into said etching solution tank.

5. An apparatus according to claim 1, further comprising:
a valve capable of shutting off and opening the flow of said nitrogen gas in said first pipe.

6. An apparatus according to claim 5, wherein
said nitrogen gas is supplied into said etching solution tank through said first pipe during a wet etching process on an intermittent basis at predetermined intervals by opening and closing said valve.

7. An apparatus according to claim 6, wherein
a period of time in that said nitrogen gas is supplied into said etching solution through said first pipe during a wet etching process, is half of the time or less in that said semiconductor wafer is dipped in the etching solution in said etching solution tank.

8. An apparatus according to claim 7, wherein
a period of time in that said nitrogen gas is supplied into said etching solution through said first pipe during a wet etching process is 1 to 3% of the time in that the semiconductor wafer is dipped in the etching solution inside said etching solution tank.

9. An apparatus according to claim 1, wherein
said etching solution contains ammonium fluoride.

10. An apparatus according to claim 9, wherein
said etching solution also contains hydrofluoric acid and acetic acid.
